(19) United States
(12) Patent Application Publication
(10) Pub. No.: US 2023/0402251 A1
(43) Pub. Date: Dec. 14, 2023

(54) GAS INJECTION SUBSYSTEM FOR USE IN AN INSPECTION SYSTEM TO INSPECT A SAMPLE BY USE OF CHARGED PARTICLES AND INSPECTION SYSTEM HAVING SUCH GAS INJECTION SUBSYSTEM

(71) Applicant: Carl Zeiss SMT GmbH, Oberkiochen (DE)

(72) Inventors: Louise Barris, North Reading, MA (US); Alexander Lombardi, Walpole, MA (US); Mark Dimanna, Fremont, NH (US); Jeffrey Sauer, Danvers, MA (US); Brett Lewis, Arlington, MA (US); Sybren Sijbrandij, Wakefield, MA (US)

(21) Appl. No.: 18/456,304

(22) Filed: Aug. 25, 2023

Related U.S. Application Data
(63) Continuation of application No. PCT/EP2022/055234, filed on Mar. 3, 2021.
(60) Provisional application No. 63/155,888, filed on Mar. 3, 2021.

(30) Foreign Application Priority Data
Mar. 25, 2021 (DE) 102021202941.8

(51) Int. Cl. H01J 37/26; H01J 37/28

(52) U.S. Cl. CPC H01J 37/261; H01J 37/28; H01J 37/3053

(57) ABSTRACT

A gas injection subsystem for use in an inspection system serves to inspect a sample by use of charged particles. At least one gas duct of the gas injection subsystem guides a gas flow from a gas reservoir to a sample inspection region. The gas duct has in the vicinity of the sample inspection region a diameter which is less than 5 mm. At least one flow control valve of the gas injection subsystem controls the gas flow through the gas duct. The valve is switchable between an open valve state in which a nominal gas flow through the gas duct is enabled and a closed valve state in which the gas duct is closed to inhibit a gas flow through the gas duct. The valve is designed such that a switching time between the open and the closed state is 100 ms at most. A gas injection subsystem results which facilitates a reproducible gas injection to the sample inspection region.

### CROSS-REFERENCE TO RELATED APPLICATIONS

The present application is a continuation of, and claims benefit under 35 USC 120 to, international application PCT/EP2022/055243, filed Mar. 2, 2022, which claims benefit under 35 USC § 119(e) to U.S. Provisional Application No. 63/155,888, filed Mar. 3, 2021, and which claims benefit under 35 USC 119 of German Application No 10 2021 202 941.8, filed Mar. 25, 2021. The entire disclosure of each these applications is incorporated by reference herein.

### FIELD

The disclosure relates to a gas injection subsystem for use in an inspection system to inspect a sample by use of charged particles. Further, the disclosure relates to an inspection system to inspect a sample by use of charged particles, the inspection system including such a gas injection subsystem.

### BACKGROUND

An inspection system to inspect a sample by use of charged particles is known from U.S. Pat. No. 8,969,835 B2.

Focused charged particle beams, i.e. Focused Ion Beams (FIBs) and Scanning Electron Microscope (SEM) electron beams can be used to modify materials at the nanoscale by introducing reactive precursor molecules to the beam-sample interaction region. Here the ion beam or electron beam dissociates or breaks these molecules to cause them to become changed so that they bind to one another or to a desired region of substrate surface. In this way, materials including electrical insulators or conductors, can be added with the nanometer patterning precision of the ion or electron beam. Alternatively, some precursor gases become chemically active when the beam hits them and they can be used to induce chemical etching with the precision of the charged particle beam. The process is facilitated by a Gas Injection Subsystem (GIS) of the inspection system.

### SUMMARY

The disclosure seeks to provide a gas injection subsystem which facilitates a reproducible gas injection to the sample inspection region.

For some processes, a molecular flux at the region of interest is precisely controlled in terms of molecules per square nanometer per second. The gas flow leaving the terminal end of the nozzle might be measured in terms of torr liters per second (TL/s), or standard cubic centimeters per minute (sccm). The gas flow may be roughly inferred by using a distant gauge on an actively pumped sample chamber. By using such a distant gauge, the gas pressure is substantially reduced far from the region of interest and background pressures unrelated to the GIS gas flux might dominate such a gauge. The gas flux may be controlled over time with within 1% accuracy or better from a target value. The gas flux may be turned on quickly (e.g. a few seconds to reach within 90% of the target value) and turned off quickly (<30 seconds to reduce the flux by a factor of 100). A process may be repeated again and again often involving repeatability of the gas flux over long intervals (e.g. hours) with a repeatability of 1% or better. In some applications a range of different gases may be delivered according to a prescribed sequence (e.g. gas species A delivered on with a prescribed flux, F1, for a time T1, then turned off within 2 seconds, then gas species B turned on with a flux value F2 for a time period T2, and then shut off within 0.5 seconds.) In some cases multiple gas species may be delivered simultaneously while controlling their partial pressures independently. A control of the gas flux with accuracy and repeatability over time may be present. A gas mixing may be minimized when this is not intended. A resulting system can be reliable and robust against failures.

The precursor chemicals may be kept separate until they reach the sample interaction region. A manifold may control the gas flow from some supply vessel to the terminal end of the nozzle which is directed at the region of interest. In some cases, the desired chemicals are provided from high pressure (e.g. 50 psi, 1500 psi) gas containment volumes (“cylinders” or “bottles”) where pressure regulators are used to reduce the gas pressure to the suitable value which less than atmospheric pressure (e.g. 5 psia, or 100 torr or 10 torr). In some cases the desired chemical comes from a solid-filled or liquid-filled container (“crucible” or “cartridge”) where the molecules evolve from the surface by evaporation or sublimation, to achieve a characteristic “equilibrium vapor pressure” above the surface. This characteristic vapor pressure can depend greatly on temperature and can be adjusted by heating or cooling the container. Because of the potential of re-condensation, the pathway that delivers the gas phase precursor to the terminal end of the nozzle may be maintained at a reliable temperature.

The terminal end of the gas nozzle may be as close as possible to the region on the sample or substrate where the ion or electron beam will be impinging. This allows the gas flux at the surface (molecules per second per mm²) to be as large as possible for the given gas flow (e.g. sccm). Multiple nozzles may be provided that can be inserted. Due to the demand that they be close to the region of interest, and their relatively large size, only one nozzle at a time may be inserted.

Charged particle instruments (SEMs, FIBs, etc) of the overall inspection system collect secondary charged particles, such as secondary electrons (SE) or secondary ions (SI), that are generated from the beam-sample interaction. This collection and detection are used to generate useful information about the sample for imaging and characterization (e.g. to facilitate proper positioning of the process area, or to monitor progress of the process). Any object near the interaction region may obstruct the path of secondary particles as they travel from the sample to the detection systems. Further, any nearby object may interfere with the electric fields which are used for collection. If the terminal end of the GIS nozzle is positioned close to the interaction region, this may be a detriment to the collection efficiency of secondary detection systems. An example of a detection system is the Everhart Thornley detector (“ET Detector”). When properly functioning an ET detector will apply an electric field by biasing its own collector screen positive with respect to the sample, and thereby attracting the (negative) secondary electron towards the collector screen. The presence of a GIS nozzle, or an array or nozzles or a manifold of nozzles may impair the functionality of such a detector. This can be mitigated by withdrawing the nozzles when not necessary, but this generally causes an image shift, and compromises performance.

With the flow control valve of the gas injection subsystem, a finally adjustable and also reproducible gas flux at the surface can be provided. The flow control valve may be designed such that the switching time between the open and the closed state is 50 ms at most, 25 ms at most, 20 ms at most, 10 ms at most, 5 ms at most, 2 ms at most or even 1 ms.

The gas injection subsystem may include an additional carrier gas supply.

A diameter of the respective gas duct in the vicinity of the sample inspection region may be less than 2 mm, less than 1 mm, less than 500 μm and may be 150 μm. Also a smaller gas duct diameter is possible, i.e. less than 250 μm. The diameter as a rule is larger than 50 μm.

A delivered gas flux at the region of interest may result that has a mean value and fluctuations attributed to e.g. a valve duty cycle such that the fluctuations are a small fraction of a mean value. Such fluctuations may be less than 20%, less than 10%, less than 5%, less than 2%, less than 1%, less than 0.5%, less than 0.2% or even less than 0.1% of the mean value of the gas flux.

A gas flux may be provided at the region of interest having a mean value of 103 or 104 or 10⁵ or 10⁶ or 10⁷ or 10⁸ molecules nm⁻² s⁻¹.

A gas flux may be delivered at the region of interest that is adjustable from 103 to 108 molecules nm⁻² s⁻¹ with an accuracy which is better than 10%, better than 5%, better than 2%, better than 1% or even better than 0.5% as compared to a set value. The gas flux provided at the region of interest may be substantially repeatable relative to a previous delivered value within 10%, within 5%, within 2, %, within 1%, within 0.5%, within 0.2% or even within 0.1%.

A volume between the final flow control valve in the gas duct and a terminal nozzle of such gas duct adjacent to the sample inspection region may be less than 0.5 cm³. A vacuum conductance of such final volume may be less than 7.5×10⁻⁴ liter/second. The vacuum conductance may be less than 7.3×10⁻⁴ liter/second for N₂ gas at typical operating temperature and pressure conditions.

A terminal value between the last flow control valve and the terminal nozzle may be so small that the gas can be shut off such that a gas flux at the sample inspection region is reduced by 50% within 5 s. In addition, the gas injection subsystem may be designed such that the gas through the respective gas duct can be turned on such that a desired gas flux at the sample inspection region is met within 50% of its final value within 5 s.

A valve having a valve housing can form a duct portion of the gas duct. This can allow for a compact valve package with low demand of available space.

The valve can have a closure member which is located within the valve housing and is switchable in an actuating direction between the open valve state and the closed valve state, the actuating direction being parallel to a gas flow direction through the duct portion. This has proven to be reliable and also to enable fast switching times. A solenoid may be used as a switching actor of such valve. The closure member may be as a whole located within the valve housing.

In some cases, the switching cycle of the valve is at most one second. A This can allow a fast change of a given gas flow rate. A switching cycle may be faster and may be 0.5 s at most, 0.2 s at most, 0.1 s at most, 0.05 s at most, 0.02 s at most, 0.01 s at most, 0.005 s at most, 0.002 s at most or even 0.001 s.

In some cases, a duty cycle, i.e. a fraction between a time span in which the valve is in the open state and the switching cycle time span, is controllable in the range between 0.01% and 100%. Such a duty cycle can give a very fine adjustable and almost continuously controllable gas flow.

The gas injection subsystem can have a plurality of gas ducts, wherein each of the gas ducts is designed to guide a respective gas flow from one of the respective plurality of gas reservoirs to the sample inspection region, wherein nozzle sections of the plurality of gas ducts are connected to a common nozzle manifold in the vicinity of the sample inspection region. Such a common nozzle manifold can allow a delivery of the plurality of for example different gases to the sample inspection region without the need to replace a terminal nozzle section by another. The nozzle manifold may provide more than two gas ducts. The nozzle manifold may be designed to connect two to ten gas flux on the receptive demand. Such manifold avoids an act of retracting and inserting an individual nozzle to interchange between gas species to be delivered to the sample inspection region. An inconsistent placement of an individual nozzle, which might introduce beam landing errors and might impair a function of nearby accessories such as a secondary electron (SE) collector, is avoided. Further, possible fragile individual needles are avoided. Individual nozzle sections of considerable and undesired wall thicknesses also are avoided.

The provision of the nozzle manifold may be such that all the axes of terminal nozzles of the nozzle manifold are aimed to a common location, which is within 100 μm from the sample inspection region or the region of interest where charged particles generated by the inspection system hit the sample. The terminal nozzles of the nozzle manifold may be within 600 μm of the sample inspection region. The nearest surface of the nozzle manifold may be within 100 μm of the sample inspection region.

A distance between the centers of adjust terminal nozzles of the nozzle manifold may be 300 μm at most.

A nozzle manifold geometry may be such that when electrically grounded, a collection of detectors being located adjacent to the sample inspection region may be greater than 80% of a nominal detector efficiency.

In some cases, in an open position and the vicinity of the inspection region, the nozzle manifold covers a solid angle of at least 1 steradian around the sample inspection region. Such a solid angle coverage of the nozzle manifold can serve as a gas atom or molecule containment using undesired loss of gas delivery. The solid angle covered by the nozzle manifold may be at least 1.5 sr, 2 sr, 2.5 sr. An upper limit of the covered solid angle may be 4 sr.

Desorbed gas atoms or molecules may be advantageously reflected back to the sample by such solid angle coverage.

The gas injection subsystem can have a movable stage to move: a nozzle section of the at least one gas duct located in the vicinity of the sample inspection region; or the nozzle manifold. Such a movable stage can allow for a fine relative position of the nozzle section or the nozzle manifold relative to the sample inspection region. The movable stage may have an xyz stage with independently controllable actors. A positioning accuracy of the movable stage may be better than 10 μm. A flexible duct portion may be positioned between the movable nozzle portion and the fixed portion of the gas duct.

The gas injection subsystem can have a pressure gauge to measure the gas pressure within the at least one gas duct, the pressure gauge being located in the gas duct in the vicinity of the nozzle section of the gas duct. Such a pressure gauge may be in signal connection with the flow control valve to modify a duty cycle of the valve depending on the measured gas pressure. The measure gauge may be positioned in the vicinity of the last flow control valve in the gas flow to the gas duct.

The gas reservoir can be embodied as a pressurized gas container and/or a temperature controlled crucible to contain a liquid with controlled vapor pressure. Such embodiments have proven to be reliable.

An inspection system to inspect a sample by use of charged particles can include a gas injection subsystem according to the disclosure and a charged particles inspection device to impinge a region of interest of a sample to be inspected with charged particles, the region of interest being located at the sample inspection region of the gas injection subsystem. Such an inspection system can yield benefits as discussed above with respect to the gas injection subsystem according to the disclosure.

### BRIEF DESCRIPTION OF THE DRAWINGS

Exemplified embodiments of the disclosure hereinafter are described with reference to the accompanied drawings.

FIG. 1 shows an embodiment of an inspection system to inspect a sample by use of charged particles, including a multi-channel gas injection subsystem of which one channel is shown having a high pressure gas supply including a pressurized cylinder as gas reservoir;

FIG. 2 shows in a schematical depiction similar to that of FIG. 1 a further embodiment of an inspection system also including a multi-channel gas injection subsystem including a low pressure crucible gas supply with a temperature controlled crucible containing a liquid with controlled vapor pressure;

FIG. 3 shows in a schematical depiction similar to that of FIG. 1 a further embodiment of an inspection system also including a multi-channel gas injection subsystem including a low pressure crucible gas supply with a temperature controlled crucible containing a liquid with controlled vapor pressure;

FIG. 4 shows a longitudinal sectional view of a flow control valve to control gas flow through a gas duct or one of the gas supply channels of the multi-channel gas injection subsystem of one of the embodiment of FIG. 1 to 3, the valve being embodied as a micro valve and shown in an open valve state;

FIG. 5 shows the valve according to FIG. 4 shown in a closed valve state;

FIG. 6 shows a perspective view of a gas nozzle manifold being part of the gas injection subsystem of one of the embodiments of FIG. 1 to 3;

FIG. 7 shows a side view of a manifold connection and body of the gas nozzle manifold shown in view direction VII of FIG. 6;

FIG. 8 shows an upper view of the connection end body shown in new direction VIII of FIG. 7; and

FIG. 9 shows a front view of the connection end body shown in view direction IX in FIG. 8.

### DETAILED DESCRIPTION

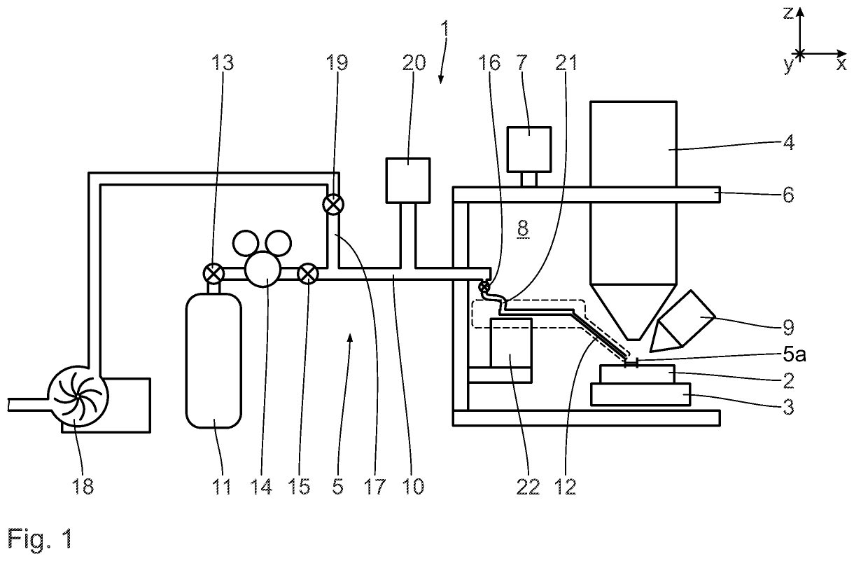

FIG. 1 shows an embodiment of an inspection system 1 to inspect a sample 2, in particular a region of interest of a surface of the sample 2 by use of charged particles. The sample 2 is held on a sample stage 3. With the sample stage 3 controlled movement of the sample 2 at least in three translation degrees of freedom is possible.

To facilitate the description of orientations and dimensions, in the following a Cartesian coordinate system is used. In FIG. 1 the x-axis is directed to the right and the y-axis is directed perpendicular to the drawing plane of FIG. 1 in the direction away from the viewer. The z-axis is directed upwards.

Depending form the embodiment of the sample stage 3, in addition to three translation degrees of freedom, further degrees of freedom to position the sample 2, are possible, i.e. up to three tilting degrees of freedom.

The inspection system 1 includes a charged particle inspection device 4, e.g. a scanning electron microscope (SEM) device or a focused ion beam (FIB) device, to impinge the region of interest of the sample 2 to be inspected with charged particles. The region of interest is located at a sample inspection region 5a of a gas injection subsystem 5 which is described in greater detail later.

The charged particle inspection device 4 is mounted on a frame 6 of the inspection system 1. Mounted to this frame 6 is further a pressure gauge measuring a gas pressure in a process chamber 8 of the charged particle inspection device 4. Within such process chamber 8, also further inspection device accessories 9 to treat or monitor the region of interest are located. Such accessories 9 can be mounted to the frame 6. The accessories 9 may include for example charged particle detectors.

The gas injection subsystem 5 is embodied as a multi-channel system to deliver a respective multitude of possibly different gas types to the region of interest. Shown in FIG. 1 is one of these channels which is embodied as a gas duct 10 to guide a gas flow from a gas reservoir 11 which is embodied as a pressurized gas container or cylinder to the sample inspection region 5a. In the vicinity of the sample inspection region 5a, the gas duct 5 is embodied as a nozzle section 12 having a terminal diameter, i.e. in the vicinity of the sample inspection region 5a, which is less than 5 mm.

The gas duct 10 or at least sections of the gas cut 10 may be maintained at a constant temperature to prevent condensation and clogging of the duct, such as of the nozzle section 12.

At least one flow control valve serves to control the gas flow through the gas duct 10. In the FIG. 1 embodiment, three flow control valves are present in sequence in the gas duct 10 between the gas reservoir 11 and the nozzle section 12. A first of these flow control valves is embodied as a cylinder valve 13 at an outlet of the gas reservoir 11. In the gas flow direction through the gas duct 10 a pressure regulator unit 14 follows. In the gas flow direction after such pressure regulator unit 14, further flow control valve embodied as a precision leak valve 15 is located. A third flow control valve in the gas duct 10 is embodied as a micro valve 16. Between the precision leak valve 15 and the micro valve 16, a vacuum duct 17 is in flow connection with the gas duct 10. This vacuum duct 17 connects the gas duct 10 to a vacuum pump 18. Between the vacuum pump 18 and inlet of the vacuum duct 17 in the gas duct 10, a vacuum rough valve 19 is located in the vacuum duct 17. Between such inlet of the vacuum duct 17 in the gas duct 10 and the micro valve 16, a further pressure gauge 20 is connected to the gas duct 10 to measure the gas pressure within the gas duct 10 in the vicinity of the inlet of the micro valve 16. The pressure gauge 20 is located in the gas duct 10 between the flow control valve 15, i.e. the pressure leak valve and the nozzle section 12 of the gas duct 10. The gauge 20 may be used to modify the duty cycle of the micro valve 16 to achieve a desired gas flux.

The pressure gauge 20 (and 7) may be embodied as thermocouple gauges, ionisation gauges, magneto gauges. Some embodiments for such gauges 20 (or 7) are diaphragm type gauges capable to read true pressure independent of ta respective gas species and independent of a respective gas temperature.

The nozzle section 12 is connected to an outlet of the micro valve 16 via a flexible tube section 21, which also is part of the gas duct 10.

The nozzle section 12 is mounted to a moveable stage 22 to move the nozzle section 12 of the gas duct 10 relative to the frame 6 of the charged particle inspection device 4. During such movement, the nozzle section 12 moves relative to those parts of the gas duct 10 upstream of the flexible tube 21. The flexible tube 21 serves to compensate such movement of those sections of the gas duct 10 relative to each other. The movable stage 22 is mounted to the frame 6. The moveable stage 22 allows a movement of the nozzle section 12 relative to the frame 6 at least along three translational degrees of freedom.

Depending on the embodiment of the movable stage 22, also at least one further tilting degree of freedom is possible. With the movable stage 22 a position of a free end of the nozzle section 12 and also a direction of such free end of the nozzle section 12 relative to the sample inspection region 5a or the region of interested respectively, can be finally adjusted.

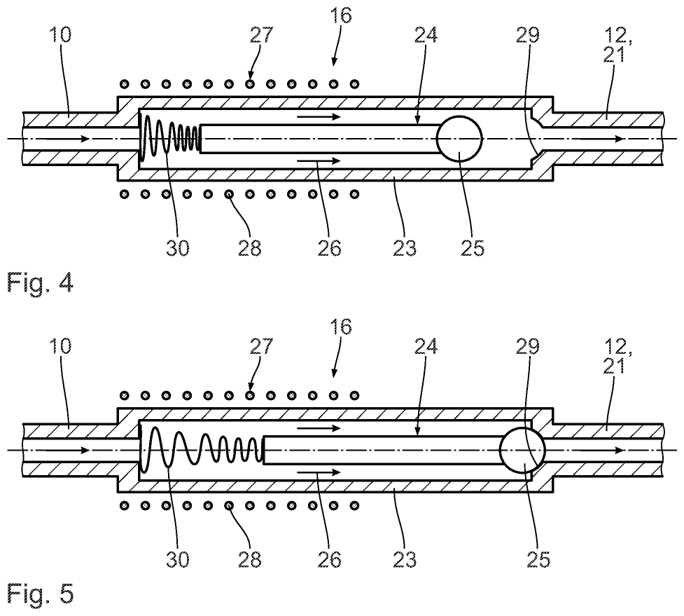

FIGS. 4 and 5 show an embodiment of the micro valve 16.

FIG. 4 shows an open valve state of the micro valve 16, wherein a nominal gas flow through the gas duct 10 is enabled. The micro valve 16 has a valve housing 23 which forms a duct portion of the gas duct 10.

A tube size of duct sections of the gas duct 10 at the inlet and at the outlet of the valve housing 23 may have a diameter which is 2 mm at most. The diameter may be close to 1.6 mm.

The micro valve 16 has a closure member 24 which is located within the valve housing 23. The closure member 24 is embodied as a plunger with a ball end 25. The closure member 24 is switchable in an actuating direction 26 between the open valve state shown in FIG. 4 and a closed valve state shown in FIG. 5. Such actuating direction 26 is parallel to a gas flow direction through the duct portion of the gas duct 10, i.e. through the valve housing 23.

In the open valve state, a nominal gas flow through the gas duct 10 is enabled.

For switching the closer member 24 between the open and the closed valve state, an actor 27 is provided which is embodied as a solenoid actor with external solenoid windings 28.

In the closed valve state of FIG. 5, the ball end 25 of the closure member 24 abuts a ceiling seat surface 29 of the valve housing 23 to close the gas duct 10 within such valve housing 23. In such closed valve state, the plunger of the closure member 24 is pretensioned via an internal spring 30 which is compressed between the free end of the plunger of the closure member 24 opposite the ball end 25 and a housing step of the valve housing 23 surrounding an inlet of the gas duct 10 into the interior of the valve housing 23. During opening of the micro valve 16, the actor 27 works against the pre-tensioning force of the spring 30.

With the actor 27, a switching time between the open and the closed valve state is achievable which is 100 ms at most. Depending on the design of the actor 27 even faster switching times are possible e.g. 50 ms at most, 25 at most, 20 ms at most, 10 ms at most, 5 ms at most, 2 ms at most or even 1 ms.

A switching cycle of the micro valve 16 may be 1 s at most.

The micro valve 16 may be cycled at 2, 5, 10, 50, 100, 200, 500 or even 1000 times per second.

A duty cycle of the micro valve 16, a fraction between a time span in which the micro valve 16 is in the open state and the switching cycle time span may be controllable in a range between 0.01% and 100%.

With the micro valve 16 a verifying control of the gas flow through the gas duct and for example the gas flow impinging the region of interest is possible.

The micro valve 16 may be heated to provide a gas condensation within the valve housing 23. The actor 27 may additionally serve as a heating device. A low level of current can be applied to the solenoid winding 28 to provide some heating without being sufficient to open the valve.

The gas injection subsystem 5 has a plurality of gas ducts according to gas duct 10. Each of the gas duct 10ᵢ of such plurality is designed to guide a respective gas flow from one of a respective plurality of gas reservoir 11ᵢ to the sample inspection region 5a.

Examples of the gases which may be guided to the sample inspection region 5a via the gas duct 10, 10ᵢ are XeF₂, W(CO)₆, Co₂(CO)₈, MePtCpMe₃, PMCPS ((CH₃SiHO)₅).

The integrated pressure gauges 20 allow for individual monitoring of the true pressure of the gas within the gas duct 10 in a section upstream of the micro valve 16. Such true pressure is linearly proportional to a gas flux delivered to the sample inspection region 5a. The true gas pressure measurement via a respective gauge 20 may be done separately for each of the gas ducts 10ᵢ. The precision leak 15 valve which is the end of a high pressure section the injection subsystem 5 is continuously adjustable from open valve state to a closed valve state allowing a gas flow to vary over several orders of magnitude. All other valves described above are designed to be either fully open or fully closed.

Although the micro valve 16 is truly binary, i.e. only has the operational states “open” or “closed”, the micro valve 16 produces a nearly continuously adjustable average gas flow rate which is repeatable and linear. The micro valve 16 may have a varying duty cycle. In each of the respective gas ducts 10ᵢ there is at least one micro valve 16 according the description above with respect in particular to FIGS. 4 and 5.

A gas shut off time is limited only by a volume and a vacuum conductance of the duct section between the micro valve 16 and the terminal nozzle of the nozzle section 12. A fast interchange and/or simultaneous provision of two and more gases via the different gas ducts 10ᵢ of the gas injection subsystem is possible.

The gas shut off time may be smaller than 10 s.

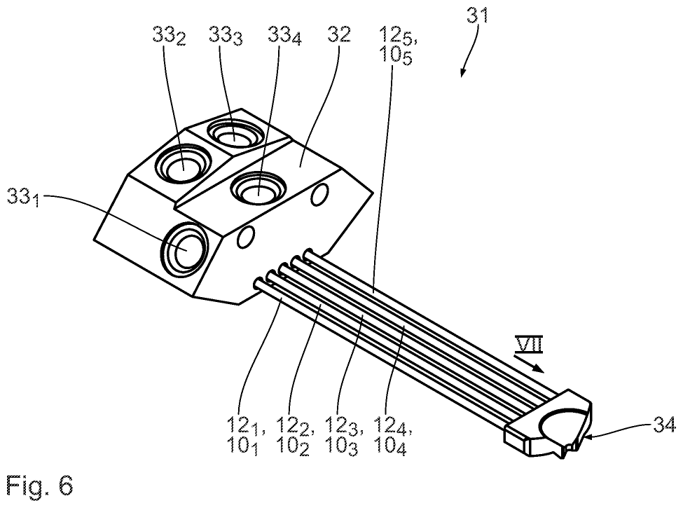

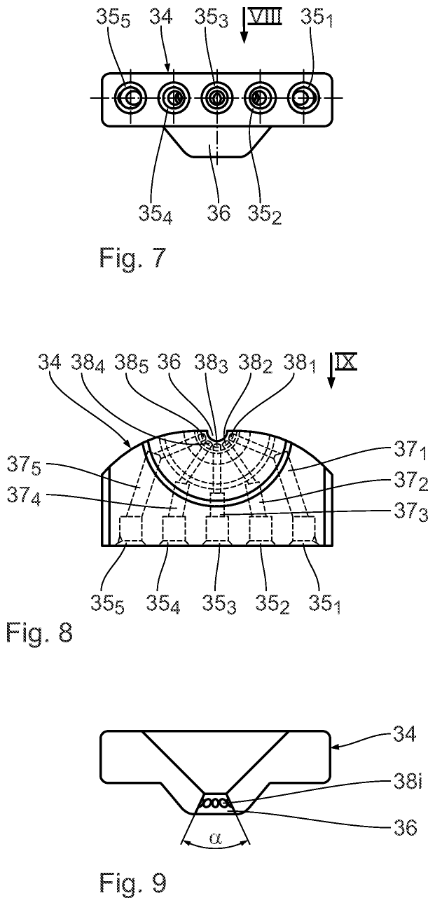

Nozzle sections of such plurality of gas ducts 10ᵢ are in an embodiment of the inspection system 1 connected to a common nozzle manifold 31 which is described with respective FIG. 6 to 9.

The nozzle manifold 31 has a main connecting body 32 shown in FIG. 6 having inlets 33ᵢ to receive complementary connecting portions of the respective gas ducts 10₁. FIG. 6 shows four inlets 33₁ to 33₄. A fifth inlet is not visible from the viewing direction of FIG. 6.

Within the main connecting body 32, the inlets 33ᵢ are connected to individual end sections/nozzle sections 12ᵢ of the respective gas ducts 10ᵢ (i=1 to 5). The end portions of the nozzle sections 12ᵢ are joined via a common end body 34 of the nozzle manifold 31. Such common end body 34 has inlets 35ᵢ to receive the nozzle sections 12ᵢ of the respective gas ducts 10ᵢ (i=1 to 5). Within the common end body 34, such inlets 35 are connected to a concave half circle shaped nozzle outlet portion 36 of the common end body 34. The nozzle ducts 37ᵢ (i=1 to 5) within such common end body 34 include nozzle duct portions with staggered reduced diameter. In the vicinity of the nozzle outlet portion 36, terminal nozzles 38ᵢ have an inner diameter which is smaller than 0.33 mm. Such diameter of the nozzle ducts 37ᵢ may be 250 μm. A separation between adjacent nozzle ducts 37 at the termination at the nozzle outlet portion 36 may be 50 μm at most. Such separation may be even smaller and may be 20 μm at most.

The concave shaped nozzle outlet portion 36 further is embodied as a cone opening downwards, i.e. opening to the sample inspection region 5a. A cone angle α of such opening cone may be in a range between 30 deg and 70 deg, between 40 deg and 60 deg and may be close to 50 deg.

Such cone section of the nozzle outlet portion 36 with the terminal nozzles 38 surrounds the sample inspection region 5a, i.e. the region of interest of the sample 2, tending a solid angle of about 2 steradian. This ensures enhanced gas containment by creating a partial enclosure to the region of interest 5a to reflect back a fraction of gas molecules that are desorbed from the surface of the sample 2. Gas atoms or molecule leaving the terminal nozzles 38 are distributed over the sample inspection region 5a, within in an area which may be about 1 mm in diameter.

Such nozzle outlet portion 36, i.e. the terminal nozzles 38 of the respective gas duct 10ᵢ is positioned in the close vicinity to the region of interest 5a, i.e. to the sample inspection region, with the help of the movable stage 22 which in this embodiment carries the main connecting body 32 of the nozzle manifold 31. Depending on the embodiment of the nozzle manifold 31, such manifold may be designed to connect two to ten gas ducts 10ᵢ.

The nozzle manifold 31 provides a compact mechanical component assuring a consistent and simultaneous replacement of the nozzle ducts 37. All of the nozzle ducts 37 of the gas ducts 10ᵢ are directed and aimed to the same sample inspection region 5a, i.e. to the region where the charged particle beam hits the region of interest of the sample 2. A switching between different gases is possible without having to interchange one terminal nozzle section by another. A displacement resolution/positioning accuracy of the movable state 22 may be at least 500 μm. Such positioning accuracy may be even better or may be better than 250 μm, better than 100 mm and even better than 25 μm, e.g. 10 μm.

The nozzle manifold 31 and for example the common end body 34 may be designed such that in an operating position in the vicinity of the sample inspection region 5a, the nozzle manifold 31 covers a solid angle of at least 1 steradian around the sample inspection region 5a. Such solid angle covered by the nozzle manifold 31 may be even larger and may be at least 1.5 steradian, 2 steradian, 2.5 steradian. Such solid angel as a rule is smaller than 4 steradian.

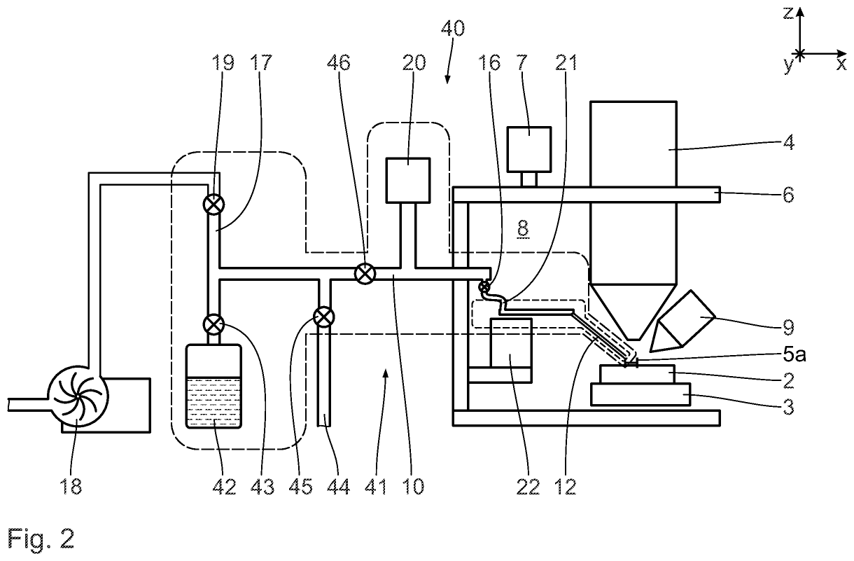

The nozzle manifold 31 may be electrically bias positively or negatively along with an electrical sample bias and/or along with an electrical detector screen bias to enhance a collection efficiency of detectors located adjacent to the sample inspection region. The nozzle manifold may be bias positively or negatively along with the sample bias and the detector screen so that the collecting efficiency of the adjacent detectors is greater than 80 With respect to FIG. 2, the further embodiment of an inspection system 14 which may be used instead of the inspection system 1 now is described. Components and functions which correspond to those which were described in respect to FIGS. 1 and 4 to 9 hereinafter have the same denominations and/or reference numerals and are not described in detail again.

A gas injection subsystem 41 of the inspection system 40 has a gas reservoir 42 which is embodied as a temperature controlled crucible contained a liquid with controlled vapour pressure.

The temperature control of the respective crucible 42 is used for determining the vapour pressure of the gas within the crucible 42 and the following gas duct 10. Thus, the respective gas reservoir 42 includes a temperature control. All downstream sections of the gas ducts after the crucible 42 are designed to be at a similar or grater temperature to prevent condensation.

An outlet of such crucible 43 is connected via a supply micro valve 43 with the gas duct 10. In the gas flow after such micro valve 43 the vacuum duct 17 is connected to the gas duct 10. After such vacuum duct inlet, a carrier gas duct 44 is connected to the gas duct 10 via a carrier gas purge micro valve 45 in the gas flow after such higher gas duct inlet a flow control micro valve 46 is present in the gas duct 10. In the gas flow after such flow control micro valve 46 the pressure gauge 20 is connected to the gas duct 10. The supply micro valve 43, the flow control micro valve 46 and the micro valve 16 adjacent to the nozzle section 12 are flow control valves to control the gas flow through the gas duct 10.

As a further flow control valve, the carrier gas purge micro valve 45 serves to control a carrier gas flow through the gas duct 10.

As carrier gas, nitrogen or a noble gas may be used.

The carrier gas may be used to purge the gas manifolds of residual gases and adsorbates in a cleaning process step of the inspection system 1.

The gas ducts 10 may contain provisions for evacuating or vacuum purging the contents to remove resident cases, and maintain clean surfaces at room temperature or during periodic baking. The individual gas ducts 10 may also include provisions for heating or cooling. The individual gas ducts 10 may at least have on temperature sensor to control the temperature to eliminate condensation.

The ducts 10, 17, 44 are made from stainless steel.

All of the micro valves 43, 45 and 46 embodied as switchable micro valve as described with reference to micro valve 16, in particular referring to FIGS. 4 and 5.

The gauge 7, 20 and also the valves 13, 15, 16, 19, 43, 45, 46 are in signal connection to a control unit of the inspection system. Such control unit is not shown in the figures.

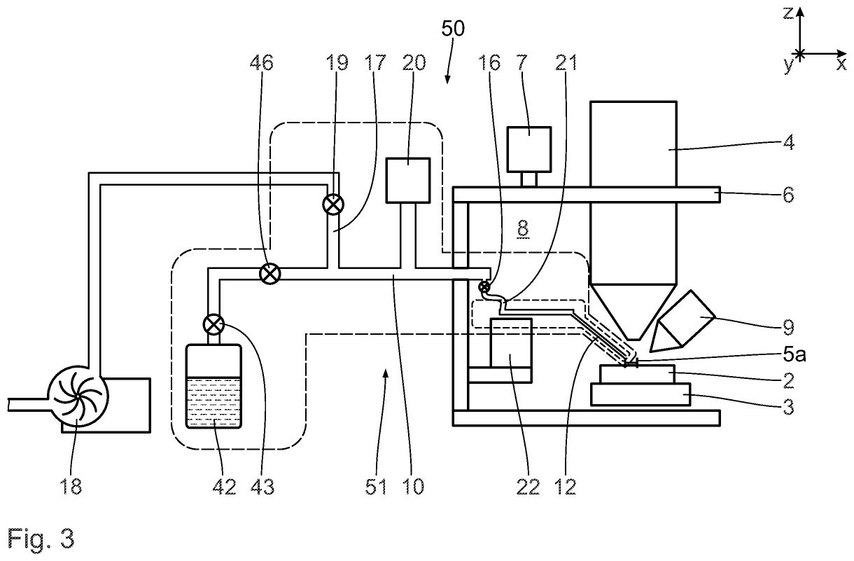

With respect to FIG. 3, a further embodiment of an inspection system 14 which may be used instead of the inspection system 1 now is described. Components and functions which correspond to those which were described in respect to FIGS. 1, 2 and 4 to 9 hereinafter have the same denominations and/or reference numerals and are not described in detail again.

In the embodiment of FIG. 3 a gas injection subsystem 51 is present having a gas reservoir 43 according to the FIG. 2 embodiment without a carrier gas supply, i.e. resembling the vacuum/gas duct design of the FIG. 1 embodiment. In the gas flow after the supply micro valve 43, there is the flow control micro valve 46 in the gas injection subsystem 51 without further duct inlet. The vacuum duct 17 is connected to the gas duct 10 in the gas flow after the flow control micro valve 46. The further design of the gas duct 10 of the gas injection subsystem 51 corresponds to the FIG. 1 embodiment of the gas injection subsystem.

What is claimed is:

1. A gas injection subsystem, comprising:
a duct configured to guide a gas flow from a gas reservoir to a sample inspection region, the duct having a diameter of less than five millimeters in a vicinity of a sample inspection region; and
a valve configured to control the gas flow through the duct, the valve being switchable between:
an open valve state in which a nominal gas flow through the duct is enabled; and
a closed valve state in which the duct is closed to inhibit a gas flow through the gas duct,
wherein the valve is configured so that a switching time between the open and the closed state is at most 100 milliseconds.

2. The gas injection subsystem of claim 1, wherein the valve comprises a valve housing which defines a duct portion of the duct.

3. The gas injection subsystem of claim 1, wherein the valve comprises a closure member located within the valve housing, the closure member is switchable in an actuating direction between the open valve state and the closed valve state, and the actuating direction is parallel to a gas flow direction through the duct portion.

4. The gas injection subsystem of claim 1, wherein a switching cycle of the valve is at most one second.

5. The gas injection subsystem of claim 1, wherein a duty cycle of the valve is controllable in a range between 0.01% and 100%.

6. The gas injection subsystem of claim 1, comprising a plurality of ducts and a common nozzle manifold, wherein each duct is configured to guide a respective gas flow from one of a respective plurality of gas reservoirs to the sample inspection region, and nozzle sections of the plurality of ducts are connected to the common nozzle manifold in the vicinity of the sample inspection region.

7. The gas injection subsystem of claim 6, wherein, when the nozzle is in an open position and in the vicinity of the inspection region, the nozzle manifold covers a solid angle of at least one steradian around the sample inspection region.

8. The gas injection subsystem of claim 6, further comprising a movable stage configured to move a member selected from the group consisting of a nozzle section of the duct located in the vicinity of the sample inspection region and the nozzle manifold.

9. The gas injection subsystem of claim 8, further comprising a pressure gauge configured to measure a gas pressure within the duct, wherein the pressure gauge is in the duct in a vicinity of the nozzle section of the gas duct.

10. The gas injection subsystem of claim 1, further comprising a pressure gauge configured to measure a gas pressure within the duct, wherein the pressure gauge is in the duct in a vicinity of a nozzle section of the gas duct.

11. The gas injection subsystem of claim 10, wherein the valve comprises a valve housing which defines a duct portion of the duct.

12. The gas injection subsystem of claim 1, further comprising a movable stage configured to move a nozzle section of the duct located in the vicinity of the sample inspection region.

13. The gas injection subsystem of claim 12, wherein the valve comprises a valve housing which defines a duct portion of the duct.

14. The gas injection subsystem of claim 1, wherein the gas reservoir comprises at least one member selected from the group consisting of a pressurized gas container and a temperature controlled crucible configured to contain a liquid with controlled vapor pressure.

15. The gas injection subsystem of claim 14, wherein the valve comprises a valve housing which defines a duct portion of the duct.

16. The gas injection subsystem of claim 1, wherein the valve comprises a closure member located within the valve housing, the closure member is switchable in an actuating direction between the open valve state and the closed valve state, and the actuating direction is parallel to a gas flow direction through the duct portion.

17. The gas injection subsystem of claim 1, wherein the valve comprises a valve housing which defines a duct portion of the duct, and a switching cycle of the valve is at most one second.

18. The gas injection subsystem of claim 1, wherein the valve comprises a valve housing which defines a duct portion of the duct, and a duty cycle of the valve is controllable in a range between 0.01% and 100%.

19. The gas injection subsystem of claim 1, comprising a plurality of ducts and a common nozzle manifold, wherein each duct is configured to guide a respective gas flow from one of a respective plurality of gas reservoirs to the sample inspection region, and nozzle sections of the plurality of ducts are connected to the common nozzle manifold in the vicinity of the sample inspection region, wherein the valve comprises a valve housing which defines a duct portion of the duct.

20. An inspection system, comprising:
a gas injection subsystem according to claim 1; and
a charged particles inspection device configured to impinge charged particles on a region of interest of a sample,
wherein the region of interest is located at the sample inspection region of the gas injection subsystem.
